(19) United States
(12) Patent Application Publication
(10) Pub. No.: US 2021/0202785 A1
(43) Pub. Date: Jul. 1, 2021

(54) SYSTEM AND METHOD FOR CIGS THIN FILM PRETREATMENT

(71) Applicant: BEIJING APOLLO DING RONG SOLAR TECHNOLOGY CO., LTD., Beijing (CN)

(72) Inventor: YI XU, Beijing (CN)

(21) Appl. No.: 16/090,025

(22) PCT Filed: Dec. 25, 2017
(86) PCT No.: PCT/CN2017/118221

§ 371 Date: Sep. 28, 2018

(30) Foreign Application Priority Data
Dec. 20, 2017 (CN) 201711385518.1

(51) Int. Cl. H01L 31/18; H01J 37/32

(52) U.S. Cl. CPC H01L 31/1844; H01J 37/32174; H01J 37/321

(57) ABSTRACT

A system for CIGS thin film pretreatment includes a RF power supply system, an inductance coil, a process chamber and a cathode plate. The inductance coil is disposed on the top of the process chamber. The cathode plate is disposed at a bottom of the process chamber. The RF power supply system is configured to power the inductance coil and the cathode plate at different power to form a RF voltage, and make the inductance coil generate rays with a specified frequency. The process chamber is configured to contain a CIGS thin film to be treated, contain a process gas, and allow the rays to enter. The process gas is capable of forming plasma under the ionization of the rays. The plasma is capable of moving toward the cathode plate and bombarding a surface of the CIGS thin film under the driving of the RF voltage.

### CROSS-REFERENCE TO RELATED APPLICATIONS

This application is a continuation of International Patent Application No. PCT/CN2017/118221 filed on Dec. 25, 2017, which claims priority to Chinese Patent Application No. 201711385518.1, filed on Dec. 20, 2017 and titled “SYSTEM AND METHOD FOR CIGS THIN FILM PRETREATMENT”, the entirety of each is incorporated herein by reference.

### TECHNICAL FIELD

The present disclosure relates to the technology field of solar cell thin film, and more particularly, to a system and method for CIGS thin film pretreatment.

### BACKGROUND

In existing solar cell technologies, copper indium gallium selenide (“CIGS” for short) thin film solar cells have the advantages of strong light absorption capability, good stability, good radiation resistance, high efficiency and low cost, and they can be made into flexible components, which are suitable for manufacturing photovoltaic cells.

### SUMMARY

In a first aspect, some embodiments of the present disclosure provide a system for CIGS thin film pretreatment. The system for CIGS thin film pretreatment comprises a radio frequency (RF for short) power supply system, an inductance coil, a process chamber and a cathode plate. The inductance coil is disposed on a top of the process chamber. The cathode plate is disposed at a bottom of the process chamber. The RF power supply system is configured to power the inductance coil and the cathode plate at different power, to form a RF voltage, and make the inductance coil generate rays with a specified frequency. The process chamber is configured to contain a CIGS thin film to be treated, contain a process gas, and allow the rays to enter. The CIGS thin film is placed above the cathode plate. The process gas is capable of forming plasma under the ionization of the rays. The plasma is capable of moving toward the cathode plate and bombarding a surface of the CIGS thin film under driving of the RF voltage.

In some embodiments, the RF power supply system comprises a first power supply which is configured to power the inductance coil, and a second power supply which is configured to power the cathode plate.

In some embodiments, the RF power supply system comprises a first adapter which is configured to adjust power supplied to the inductance coil, and a second adapter which is configured to adjust power supplied to the cathode plate.

In some embodiments, the RF power supply system further comprises a first power supply, a second power supply, a first adapter and a second adapter. The first power supply is configured to power the inductance coil via the first adapter. The second power supply is configured to power the cathode plate via the second adapter. The first adapter is configured to adjust power from the first power supply supplied to the inductance coil. The second adapter is configured to adjust power from the second power supply supplied to the cathode plate.

In some embodiments, the RF power supply system is configured to power the inductance coil at first power and power the cathode plate at second power, wherein the first power is greater than the second power.

In some embodiments, a quartz cover is disposed at the top of the process chamber. The quartz cover is configured to allow the rays to pass therethrough to enter the process chamber.

In some embodiments, the inductance coil is a copper coil and is provided in a spiral shape.

In some embodiments, the first adapter and the second adapter are configured to adjust power by adjusting a current.

In some embodiments, the first adapter comprises a first capacitor which is a tunable capacitor and is connected with the inductance coil in series, and a second capacitor which is a fixed capacitor and is connected with the inductance coil in parallel.

In some embodiments, the first adapter is configured as a starter to provide a starting effect on the RF voltage.

In some embodiments, the system for CIGS thin film pretreatment further comprises a heating device which is disposed in the process chamber and configured to maintain a temperature of the process gas within a preset temperature range.

In a second aspect, some embodiments of the present disclosure provide a method for CIGS thin film pretreatment, to which the system for CIGS thin film pretreatment according to the first aspect is applied. The method for CIGS thin film pretreatment comprises:

placing a CIGS thin film above the cathode plate in the process chamber;

injecting a process gas into the process chamber; and

powering, by the RF power supply system, the inductance coil at first power and the cathode plate at second power, wherein the first power is greater than the second power, such that a RF voltage is formed between the inductance coil and the cathode plate, and the inductance coil generates rays with a specified frequency, wherein

the rays enter the process chamber under driving of the RF voltage, making the process gas form plasma, and the plasma moves, under the driving of the RF voltage, toward the cathode plate and bombards a surface of the CIGS thin film.

In some embodiments, the CIGS thin film is located on a substrate. The step of placing the CIGS thin film above the cathode plate in the process chamber is: placing the substrate having the CIGS thin film on its surface above the cathode plate in the process chamber.

In some embodiments, the RF power supply system comprises a first power supply and a second power supply. Powering, by the RF power supply system, the inductance coil at the first power and the cathode plate at the second power comprises:

powering, by the first power supply, the inductance coil at the first power; and

powering, by the second power supply, the cathode plate at the second power.

In some embodiments, the RF power supply system comprises a first adapter and a second adapter. Powering, by the RF power supply system, the inductance coil at the first power and the cathode plate at the second power comprises:

powering, by the RF power supply system, the inductance coil and the cathode plate;

adjusting, by the first adapter, power supplied to the inductance coil to be the first power; and

adjusting, by the second adapter, power supplied to the cathode plate to be the second power.

In some embodiments, the RF power supply system further comprises: a first power supply, a second power supply, a first adapter and a second adapter. Powering, by the RF power supply system, the inductance coil at the first power and the cathode plate at the second power comprises:

powering, by the first power supply, the inductance coil at the first power via the first adapter; and

powering, by the second power supply, the cathode plate at the second power via the second adapter.

In some embodiments, the first adapter and the second adapter adjust power by adjusting a current respectively.

In some embodiments, a quartz cover is disposed at a top of the process chamber. The rays enter the process chamber through the quartz cover under the driving of the RF voltage.

In some embodiments, the process gas is argon.

In some embodiments, the method for CIGS thin film pretreatment further comprises: maintaining a temperature of the process gas within a preset temperature range.

### BRIEF DESCRIPTION OF THE DRAWINGS

In order to describe embodiments of the present disclosure more clearly, the accompanying drawings to be used in embodiments will be introduced briefly.

FIG. 1 is a schematic diagram of a system for CIGS thin film pretreatment provided in some embodiments of the present disclosure.

FIG. 2 is a flow chart of a method for CIGS thin film pretreatment provided in some embodiments of the present disclosure.

### DETAILED DESCRIPTION

In order to enable those skilled in the art to understand solutions of embodiments of the present disclosure better, embodiments of the present disclosure will be further described in detail below with reference to the accompanying drawings and the implementations.

In the preparation process of a CIGS thin film, it mainly uses plasma deposition. Plasma is a set composed of free charged particles which do random motion. The simplest formation method of the plasma is to drive two plates by a radio frequency (“RF” for short) voltage source, making low-pressure gas between the two plates generate a discharge phenomenon. When a current flows from one plate to the other, the gas is “punctured” to generate the plasma. Plasma discharge can produce substance with chemical activity which is deposited on a surface layer of a substrate to form the thin film.

However, an excessively high plasma density easily causes excessive damage to a surface of the substrate, resulting in excessive defects in a prepared thin film, which seriously affects the efficiency of a device. Moreover, the higher a RF frequency is, the less uniform a plasma distribution is, which may result in poor film formation uniformity on the surface of the substrate. Therefore, the surface smoothing treatment for the CIGS thin film has great application prospects and economic values.

In view of the problem that a surface of a CIGS thin film of a current solar cell is uneven and irregular, the present disclosure provides a system and a method for CIGS thin film pretreatment. An inductance coil and a cathode plate are powered by a RF power supply to form a RF voltage, so that rays generated by the inductance coil makes a process gas in a process chamber form plasma, and the plasma bombards an uneven surface of the CIGS thin film, thereby obtaining a flatter surface of the thin film. Therefore, the absorption rate and the stability of the CIGS thin film solar cell are improved.

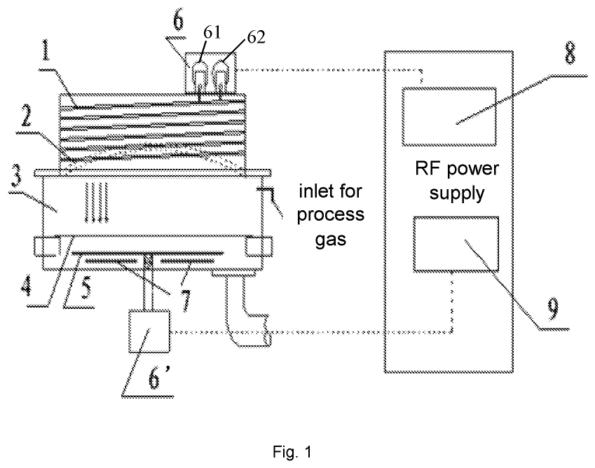

As shown in FIG. 1, some embodiments of the present disclosure provide a system for CIGS thin film pretreatment. The system includes a RF power supply system, an inductance coil 1, a process chamber 3 and a cathode plate 5. The inductance coil 1 is disposed on the top of the process chamber 3, for example, circumferentially disposed on the top of the process chamber 3. The cathode plate 5 is disposed at a bottom of the process chamber 3. Between the inductance coil 1 and the cathode plate 5, it is configured to place a substrate 4. The RF power supply system is configured to power the inductance coil 1 and the cathode plate 5 at different power, to form a RF voltage, and make the inductance coil 1 generate rays with a specified frequency. The process chamber 3 is configured to contain the CIGS thin film to be treated, contain a process gas, and allow the rays to enter. The CIGS thin film is placed above the cathode plate 5. The process gas is capable of forming the plasma under the ionization of the rays. The plasma is capable of moving toward the cathode plate 5 and bombarding the surface of the CIGS thin film under the driving of the RF voltage.

When the plasma is bombarding the surface of the CIGS thin film, the bombardment intensity decays rapidly as the distance increases. In some cases that the surface of the CIGS thin film has uneven defects, the CIGS thin film is treated by using the system for CIGS thin film pretreatment provided in some embodiments of the present disclosure. Under the bombardment of the plasma, a bulge on the surface of the CIGS thin film is closer to a plasma source, and it is subjected to more bombardment, so that the bulge becomes smaller; while a recession on the surface of the CIGS thin film is farther away from the plasma source, and it is subjected to less bombardment. As a result, a difference between the bulge and the recession is gradually reduced, making the plating get flatter.

In some embodiments, a quartz cover 2 is disposed at the top of the process chamber 3. The quartz cover 2 is configured to allow the rays to pass therethrough to enter the process chamber 3.

In some embodiments, a sample holder is disposed in the process chamber 3. The sample holder is disposed above the cathode plate and configured to support the CIGS thin film.

In some embodiments, the RF power supply system includes a first power supply 8 and a second power supply 9. The first power supply 8 is configured to power the inductance coil 1. The second power supply 9 is configured to power the cathode plate 5.

In some embodiments, the RF power supply system includes a first adapter 6 and a second adapter 6′. The first adapter 6 is configured to adjust the power supplied to the inductance coil 1. The second adapter 6′ is configured to adjust the power supplied to the cathode plate 5.

In some embodiments, the RF power supply system includes a first power supply 8, a second power supply 9, a first adapter 6 and a second adapter 6′. The first power supply 8 is configured to power the inductance coil 1 via the first adapter 6. The second power supply 9 is configured to power the cathode plate 5 via the second adapter 6′. The first adapter 6 is configured to adjust the power from the first power supply 8 supplied to the inductance coil 1. The second adapter 6′ is configured to adjust the power from the second power supply 9 supplied to the cathode plate 5.

In some embodiments, the RF power supply system is configured to power the inductance coil 1 at first power and power the cathode plate 5 at second power, wherein the first power is greater than the second power.

In some embodiments, the first adapter 6 and the second adapter 6′ are configured to adjust power by adjusting a current. In some embodiments, the first adapter 6 includes a first capacitor 61 and a second capacitor 62. The first capacitor 61 is a tunable capacitor and is connected with the inductance coil 1 in series. The second capacitor 62 is a fixed capacitor and is connected with the inductance coil 1 in parallel.

It should be noted that, in some embodiments, the first adapter 6 is further configured as a starter to provide a starting effect on the RF voltage. For example, the starting is achieved by the discharge of the first capacitor 61 and the second capacitor 62. In some embodiments, capacitors with high quality and large capacity are used. In some embodiments, capacitance capacities of the two capacitors are 5000 pf and 3000 pf, respectively. In some embodiments, the two capacitors are fixed to parallel rails and are driven by two motors to move parallelly. During a commissioning process, an appropriate power release point is obtained by adjusting positions of the two capacitors.

In some embodiments, the inductance coil 1 is a Cu (copper) coil and is spiral. In some embodiments, the copper coil is made of a high quality oxygen-free copper material, and is formed into a spiral circular shape by a copper wire having a diameter of 8 mm, which is raised by about 5 cm per turn and has a total height of about 40 cm. The greater a pitch between two turns of the Cu coil is, the smaller the density of produced plasma is, then the greater a generated capacitance is; conversely, the greater the density of the produced plasma is, the smaller the generated capacitance is. It is able to set the specific structure of the Cu coil according to actual needs, to find a suitable balance point between the plasma density and the capacitance, which can be verified by experiments.

In some practical use embodiments, the process gas is argon. In some other practical use embodiments, the process gas is another inert gas.

In some practical use embodiments, the CIGS thin film is on the substrate 4. In some embodiments, the substrate 4 is a glass substrate. In some embodiments, the substrate 4 is a flexible substrate, for example, material of the flexible substrate is titanium metal, stainless steel, or polyimide.

Further, in some embodiments, the system for CIGS thin film pretreatment further includes a heating device 7. The heating device 7 is disposed in the process chamber 3 and is configured to maintain the temperature of the process gas in the process chamber 3 within a preset temperature range.

For example, in some embodiments, the RF power supply system adopts a power supply of 13.56 MHz and of 10 kW or more. It discharges to the Cu coil via the first capacitor 61 and the second capacitor 62. Strong rays formed by the Cu coil enter the process chamber 3 through the quartz cover which is transparent, ionizing the process gas Ar. The process gas is ionized to produce the plasma. The plasma bombards toward the glass substrate, and accordingly a surface of a CIGS thin film layer on the glass substrate is uniformly etched. The surface of the thin film layer which has been etched has good uniformity, which can improve the uniformity of the CIGS thin film layer and the optical absorption efficiency thereof in the future.

The present disclosure provides a system for CIGS thin film pretreatment. The system supplies power to the inductance coil and the cathode plate via the RF power supply system so as to form the RF voltage, so that the rays generated by the inductance coil enter the process chamber and make the process gas therein form the plasma, and the plasma bombards the uneven surface of the CIGS thin film, making it be flatter. It improves the existing CIGS thin film with the problem of a surface being uneven and out-of-flatness, and the thin film having a flatter surface can be obtained. Therefore, the absorption rate and stability of the CIGS thin film solar cell can be improved.

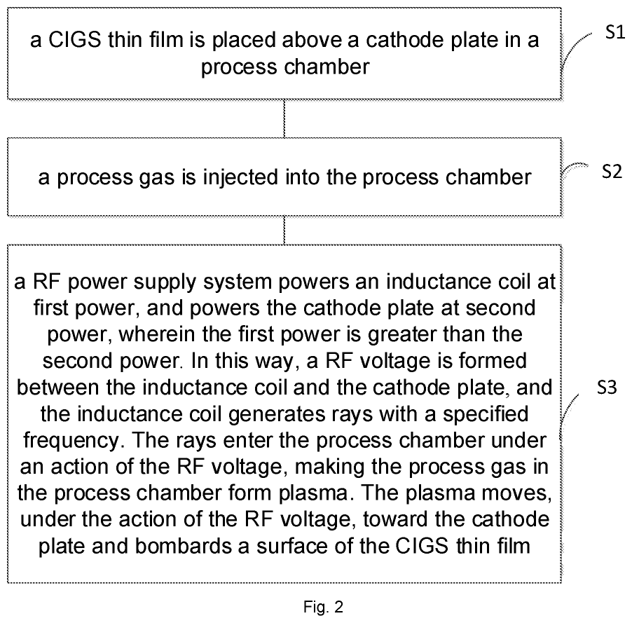

As shown in FIG. 2, some embodiments of the present disclosure further provide a method for CIGS thin film pretreatment. The foregoing system for CIGS thin film pretreatment is applied to the method. The method for CIGS thin film pretreatment includes the following steps 1 to 3 (S1˜S3).

S1. A CIGS thin film is placed above a cathode plate 5 in a process chamber 3.

S2. A process gas is injected into the process chamber 3.

S3. A RF power supply system powers an inductance coil 1 at first power, and powers the cathode plate 5 at second power, wherein the first power is greater than the second power. In this way, a RF voltage is formed between the inductance coil and the cathode plate, and the inductance coil generates rays with a specified frequency. The rays enter the process chamber 3 under the driving of the RF voltage, making the process gas in the process chamber 3 form plasma. The plasma moves, under the driving of the RF voltage, toward the cathode plate 5 and bombards a surface of the CIGS thin film.

The bombardment of the plasma flattens an uneven surface of the CIGS thin film.

In some embodiments, the CIGS thin film is located on a substrate 4, S1 is performed in S11 as follows.

S11. The substrate 4 having the CIGS thin film on its surface is placed above the cathode plate in the process chamber 3.

For example, the substrate 4 having the CIGS thin film on its surface is placed on a sample holder in the process chamber 3.

In some embodiments, the RF power supply system includes a first power supply 8 and a second power supply 9. Here, S3 includes steps 31 to 32 (S31˜S32) as follows.

S31. The first power supply 8 powers the inductance coil 1 at the first power.

S32. The second power supply 9 powers the cathode plate 5 at the second power.

In some embodiments, the RF power supply system includes a first adapter 6 and a second adapter 6′. Here, S3 includes steps 33 to 35 (S33˜S35) as follows.

S33. The RF power supply system powers the inductance coil 1 and the cathode plate 5.

S34. The first adapter 6 adjusts the power supplied to the inductance coil 1 to be the first power.

S35. The second adapter 6′ adjusts the power supplied to the cathode plate 5 to be the second power.

In some embodiments, the RF power supply system includes a first power supply 8, a second power supply 9, a first adapter 6 and a second adapter 6′. Here, S3 includes steps 36 to 37 (S36˜S37) as follows.

S36. The first power supply 8 powers the inductance coil 1 at the first power via the first adapter 6.

S37. The second power supply 9 powers the cathode plate 5 at the second power via the second adapter 6′.

In some embodiments, the first adapter 6 and the second adapter 6′ adjust power by adjusting a current.

In some embodiments, the first adapter 6 adjusts a current such that the inductance coil 1 generates the rays with a specified frequency.

In some embodiments, the first adapter 6 provides a starting effect on the RF voltage.

In some embodiments, a quartz cover 2 is disposed at a top of the process chamber 3. Here, S3 includes: the rays enter the process chamber 3 through the quartz cover 2 under the driving of the RF voltage.

In some embodiments, the process gas is argon.

In some embodiments, the method further includes the following step 4 (S4). S4. The temperature of the process gas is maintained within a preset temperature range.

The present disclosure provides a method for CIGS thin film pretreatment. The inductance coil 1 and the cathode plate 5 are powered by the RF power supply system, forming a RF voltage, and making the inductance coil 1 generate rays. The rays enter the process chamber, making the process gas therein form the plasma. The plasma bombards the uneven surface of the CIGS thin film under the driving of the RF voltage. It improves the existing CIGS thin film with the problem of the surface being uneven and out-of-flatness. Therefore, the thin film having a flatter surface can be obtained, and the absorption rate and stability of the CIGS thin film solar cell can be improved.

Configurations, features and effects of the present disclosure have been explained in detail by the above embodiments. The above are only a part of the embodiments of the present disclosure, and the protection scope of the present disclosure is not limited thereto. Any changes made in accordance with the conceptions of the present disclosure, or equivalent embodiments modified to equivalent changes without departing from the spirit of the specification and the drawings, are intended to be included within the scope of the present disclosure.

Additional embodiments including any one of the embodiments described above may be provided by the disclosure, where one or more of its components, functionalities or structures is interchanged with, replaced by or augmented by one or more of the components, functionalities or structures of a different embodiment described above.

What is claimed is:

1. A system for CIGS thin film pretreatment, comprising a radio frequency (RF) power supply system, an inductance coil, a process chamber and a cathode plate, wherein,
the inductance coil is disposed on a top of the process chamber;
the cathode plate is disposed at a bottom of the process chamber;
the RF power supply system is configured to power the inductance coil and the cathode plate at different power, to form a RF voltage, and make the inductance coil generate rays with a specified frequency; and
the process chamber is configured to contain a CIGS thin film to be treated, contain a process gas, and allow the rays to enter, wherein
the CIGS thin film is placed above the cathode plate, the process gas is capable of forming plasma under ionization of the rays, and the plasma is capable of moving toward the cathode plate and bombarding a surface of the CIGS thin film under driving of the RF voltage.

2. The system for CIGS thin film pretreatment according to claim 1, wherein the RF power supply system comprises:
a first power supply which is configured to power the inductance coil; and
a second power supply which is configured to power the cathode plate.

3. The system for CIGS thin film pretreatment according to claim 1, wherein the RF power supply system comprises:
a first adapter which is configured to adjust power supplied to the inductance coil; and
a second adapter which is configured to adjust power supplied to the cathode plate.

4. The system for CIGS thin film pretreatment according to claim 3, wherein the RF power supply system further comprises a first power supply and a second power supply, wherein
the first power supply is configured to power the inductance coil via the first adapter,
the second power supply is configured to power the cathode plate via the second adapter,
the first adapter is configured to adjust power from the first power supply supplied to the inductance coil, and
the second adapter is configured to adjust power from the second power supply supplied to the cathode plate.

5. The system for CIGS thin film pretreatment according to claim 1, wherein the RF power supply system is configured to power the inductance coil at first power and power the cathode plate at second power, wherein the first power is greater than the second power.

6. The system for CIGS thin film pretreatment according to claim 1, wherein a quartz cover is disposed at the top of the process chamber, and the quartz cover is configured to allow the rays to pass therethrough to enter the process chamber.

7. The system for CIGS thin film pretreatment according to claim 1, wherein the inductance coil is a copper coil and is provided in a spiral shape.

8. The system for CIGS thin film pretreatment according to claim 3, wherein the first adapter and the second adapter are configured to adjust power by adjusting a current.

9. The system for CIGS thin film pretreatment according to claim 3, wherein the first adapter comprises:
a first capacitor which is a tunable capacitor and is connected with the inductance coil in series; and
a second capacitor which is a fixed capacitor and is connected with the inductance coil in parallel.

10. The system for CIGS thin film pretreatment according to claim 3, wherein the first adapter is configured as a starter to provide a starting effect on the RF voltage.

11. The system for CIGS thin film pretreatment according to claim 1, further comprising:
a heating device which is disposed in the process chamber and configured to maintain a temperature of the process gas within a preset temperature range.

12. A method for CIGS thin film pretreatment, to which the system for CIGS thin film pretreatment according to claim 1 is applied, the method comprising:
placing a CIGS thin film above the cathode plate in the process chamber;
injecting a process gas into the process chamber; and
powering, by the RF power supply system, the inductance coil at first power and the cathode plate at second power, wherein the first power is greater than the second power, such that a RF voltage is formed between the inductance coil and the cathode plate, and the inductance coil generates rays with a specified frequency, wherein
the rays enter the process chamber under driving of the RF voltage, making the process gas form plasma, and the plasma moves, under the driving of the RF voltage, toward the cathode plate and bombards a surface of the CIGS thin film.

13. The method for CIGS thin film pretreatment according to claim 12, wherein the CIGS thin film is located on a substrate, and a step of placing the CIGS thin film above the cathode plate in the process chamber is:
placing the substrate having the CIGS thin film on its surface above the cathode plate in the process chamber.

14. The method for CIGS thin film pretreatment according to claim 12, wherein the RF power supply system comprises: a first power supply and a second power supply; and
powering, by the RF power supply system, the inductance coil at the first power and the cathode plate at the second power comprises:
powering, by the first power supply, the inductance coil at the first power, and
powering, by the second power supply, the cathode plate at the second power.

15. The method for CIGS thin film pretreatment according to claim 12, wherein the RF power supply system comprises a first adapter and a second adapter; and
powering, by the RF power supply system, the inductance coil at the first power and the cathode plate at the second power comprises:
powering, by the RF power supply system, the inductance coil and the cathode plate,
adjusting, by the first adapter, power supplied to the inductance coil to be the first power, and
adjusting, by the second adapter, power supplied to the cathode plate to be the second power.

16. The method for CIGS thin film pretreatment according to claim 15, wherein the RF power supply system further comprises: a first power supply and a second power supply; and
powering, by the RF power supply system, the inductance coil at the first power and the cathode plate at the second power comprises:
powering, by the first power supply, the inductance coil at the first power via the first adapter, and
powering, by the second power supply, the cathode plate at the second power via the second adapter.

17. The method for CIGS thin film pretreatment according to claim 15, wherein the first adapter and the second adapter adjust power by adjusting a current respectively.

18. The method for CIGS thin film pretreatment according to claim 12, wherein a quartz cover is disposed at a top of the process chamber, and
the rays enter the process chamber through the quartz cover under the driving of the RF voltage.

19. The method for CIGS thin film pretreatment according to claim 12, wherein the process gas is argon.

20. The method for CIGS thin film pretreatment according to claim 12, further comprising:
maintaining a temperature of the process gas within a preset temperature range.
